(19) United States
(12) Patent Application Publication
(10) Pub. No.: US 2015/0009441 A1
(43) Pub. Date: Jan. 8, 2015

(54) LCD PANEL AND A METHOD OF MANUFACTURING THE SAME

(71) Applicants: Jiali Jiang, Shenzhen (CN); Peng Du, Shenzhen (CN); Shihchyn Lin, Shenzhen (CN)

(72) Inventors: Jiali Jiang, Shenzhen (CN); Peng Du, Shenzhen (CN); Shihchyn Lin, Shenzhen (CN)

(73) Assignee: Shenzhen China Star Optoelectronics Technology Co. Ltd., Shenzhen (CN)

(21) Appl. No.: 13/502,742

(22) PCT Filed: Mar. 23, 2012
(86) PCT No.: PCT/CN12/72962

§ 371 Date: Apr. 19, 2012

(30) Foreign Application Priority Data
Mar. 22, 2012 (CN) 201210078984.6

(51) Int. Cl. G02F 1/1362; H01L 21/283; H01L 21/768; G02F 1/1368; H01L 27/12

(52) U.S. Cl. CPC G02F 1/136227; G02F 1/136286; G02F 1/1368; H01L 27/1259; H01L 21/76802; H01L 21/283; G02F 2001/13606
USPC 349/43; 438/158

(57) ABSTRACT

The present invention proposes an LCD panel. Conducting traces traversing a scan line and a voltage controlling line are made of a transparent conducting layer which are used for first and second sub-pixel electrodes, rather than a second metallic layer for data lines. Compared with the conventional technology in which the transparent conducting layer is separated from the second metallic layer used as the data lines by the insulating layer, the transparent conducting layer is separated from the first metallic layer used as the scan lines by the insulating layer and the passivation layer in the present invention. Since the parasitic capacitances across the conducting traces and the scan lines or the voltage controlling lines are lower, RC delay is reduced.

### BACKGROUND OF THE INVENTION

1. Field of the Invention

The present invention relates to a liquid crystal display (LCD) panel and a method of manufacturing the same, and more particularly, to an LCD panel capable of reducing parasitic capacitances and a method of manufacturing the same.

2. Description of the Prior Art

An advanced monitor with multiple functions is an important feature for use in current consumer electronic products. Liquid crystal displays (LCDs) which are colorful monitors with high resolution are widely used in various electronic products such as monitors for mobile phones, personal digital assistants (PDAs), digital cameras, laptop computers, and notebook computers.

Thin-film transistor liquid crystal display (TFT-LCD) has advantages in that it provides higher image quality, minimizes the use of the space, consumes less power, emits no radiation, etc., so the TFT-LCD has become the mainstream product of the market stage by stage. Further, a high contrast ratio, a fast response time, and wide viewing angles are desired aspects of any LCD at present.

When a user views images at a large viewing angle from an LCD panel, the user may find the images to be distorted. This is because colors shown on the images deviate from the original colors which should be shown. In order to inhibit color washout, various pixel structures are developed. Referring to FIG. 1, FIG. 1 is a design diagram showing a pixel structure CS07 capable of inhibiting color washout. The pixel structure CS07 adopts two sub-pixel electrodes 11 and 12. But parasitic capacitances C_{gs}_{_{—}}^{main}, C_{gs}_{_{—}}^{sub}, and C_{gs}_{_{—}}^{cx} are formed between a scan line 15 and a voltage controlling line 16 by a transistor 14 and a conducting trace connecting the sub-pixel electrodes 11 and 12 in the traditional pixel structure CS07 10. In other words, the RC delay occurring in driving signals can be effectively reduced as long as a pixel capable of educing capacitances is created.

### SUMMARY OF THE INVENTION

It is therefore an object of the present invention to provide an LCD panel and a method of manufacturing the same. In the present invention, scan lines and voltage controlling lines are disposed between a first sub-pixel electrode and a second sub-pixel electrode. An insulating layer and a passivation layer are disposed between a transparent conducting layer and a first metallic layer used as the scan lines in the present invention while only the insulating layer is disposed between the transparent conducting layer and a second metallic layer used as data lines in the conventional technology. Thus, parasitic capacitances among conducting traces and the scan lines and the voltage controlling lines which are traversed by the conducting traces are lower in the present invention. Owing to lower parasitic capacitances, the RC delay is reduced, solving problems occurring in the conventional technology.

According to the present invention, a liquid crystal display (LCD) panel comprises a glass substrate; a thin-film transistor (TFT), comprising a gate, a source, and a drain; a first sub-pixel electrode and a second sub-pixel electrode, electrically connected to the TFT and formed by a transparent conducting layer; a scan line, formed by a first metallic layer, disposed on the glass substrate, and coupled to the gate of the TFT, for transmitting a scan signal; a voltage controlling line, formed by the first metallic layer and disposed on the glass substrate, for transmitting a control signal; an insulating layer, disposed on the scan line and on the voltage controlling line; a data line, formed by a second metallic layer, disposed on the insulating layer, and coupled to the source of the TFT; a passivation layer, disposed in the second metallic layer; and a first via and a second via, formed in the passivation layer and disposed between the scan line and the voltage controlling line, wherein the first sub-pixel electrode is electrically connected to the drain of the TFT through the first via, and the second sub-pixel electrode is electrically connected to the drain of the TFT through the second via.

In one aspect of the present invention, the TFT further comprises a first conducting trace, a second conducting trace, and a third conducting trace, the source directly connected to the data line through the first conducting trace, the drain directly connected to the first sub-pixel electrode through the second conducting trace and the first via, and the drain directly connected to the second sub-pixel electrode through the third conducting trace and the second via.

In another aspect of the present invention, a projection of the first via and the second via onto the glass substrate is between a projection of the scan line and a projection of the voltage controlling line onto the glass substrate.

In still another aspect of the present invention, the transparent conducting layer is made of indium tin oxide (ITO).

In yet another aspect of the present invention, the TFT, the scan line, and the voltage controlling line disposed between the first sub-pixel electrode and the second sub-pixel electrode.

According to the present invention, a method of manufacturing an LCD panel comprises the steps of: providing a glass substrate; forming a first metallic layer on the glass substrate; etching the first metallic layer to form a gate of a TFT, a voltage controlling line and a scan line; forming an insulating layer on the gate of the TFT, the voltage controlling line, and the scan line; forming a second metallic layer and etching the second metallic layer to form a source and a drain of the TFT and a data line; forming a passivation layer on the second metallic layer; etching the passivation layer to form a first via and a second via, the first and second vias disposed between the scan line and the voltage controlling line; and forming a transparent conducting layer and etching the transparent conducting layer to form a first sub-pixel electrode and a second sub-pixel electrode, wherein the first sub-pixel electrode is electrically connected to the drain of the TFT through the first via, and the second sub-pixel electrode is electrically connected to the drain of the TFT through the second via.

In one aspect of the present invention, the step of etching the transparent conducting layer to form a first sub-pixel electrode and a second sub-pixel electrode further comprises etching the transparent conducting layer to form a first conducting trace, a second conducting trace, and a third conducting trace, so that the source directly connected to the data line through the first conducting trace, the drain directly connected to the first sub-pixel electrode through the second conducting trace and the first via, and the drain directly connected to the second sub-pixel electrode through the third conducting trace and the second via.

In another aspect of the present invention, a projection of the first via and the second via onto the glass substrate is between a projection of the scan line and a projection of the voltage controlling line onto the glass substrate.

In still another aspect of the present invention, the transparent conducting layer is made of indium tin oxide (ITO).

In yet another aspect of the present invention, the TFT, the scan line, and the voltage controlling line disposed between the first sub-pixel electrode and the second sub-pixel electrode.

In contrast to the prior art, a first via for connecting the first sub-pixel electrode and a drain of a TFT and a second via for connecting the second sub-pixel electrode and the drain of the TFT are disposed between the scan lines and the voltage controlling lines. Moreover, the conducting traces traversing the scan lines and the voltage controlling lines are used as the transparent conducting layer for the first and second sub-pixel electrodes. In the conventional technology, the conducting traces traversing the scan lines and the voltage controlling lines are used as the second metallic layer for the data lines. The conducting trace traversing the scan line or the voltage controlling line induces a parasitic capacitance. So, the farther the distance between the conducting trace and the scan line and the voltage controlling line is, the lower the parasitic capacitance is. Compared with the conventional technology in which the transparent conducting layer is separated from the second metallic layer used as the data lines only by the insulating layer, the transparent conducting layer is separated from the first metallic layer used as the scan lines by the insulating layer and the passivation layer in the present invention. The parasitic capacitances of the conducting traces and the scan lines and the voltage controlling lines traversed by the conducting traces are lower in the present invention. Therefore, the RC delay is reduced in the present invention.

These and other features, aspects and advantages of the present disclosure will become understood with reference to the following description, appended claims and accompanying figures.

### BRIEF DESCRIPTION OF THE DRAWINGS

FIG. 1 is a design diagram showing a pixel structure CS07 capable of inhibiting color washout.

FIG. 2 is a schematic diagram of an LCD panel according to a preferred embodiment of the present invention.

FIGS. 3 to 6 show the processes of forming the LCD panel.

### DETAILED DESCRIPTION OF THE PREFERRED EMBODIMENTS

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

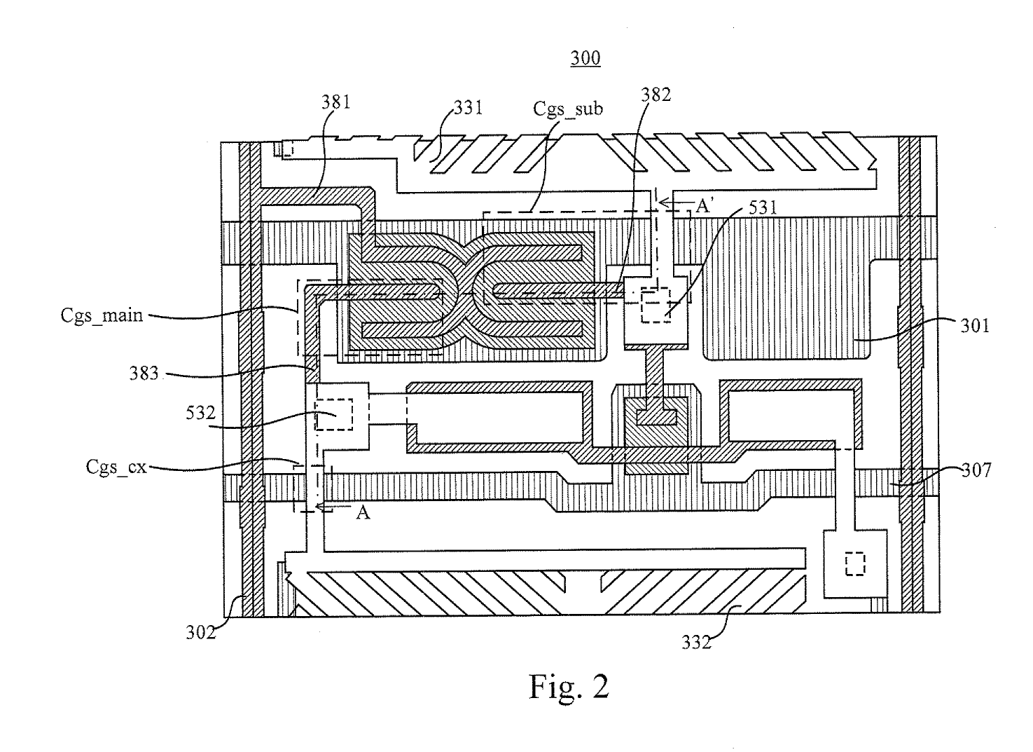

Referring to FIG. 2, a simplified schematic diagram of an LCD panel 300 according to a preferred embodiment of the present invention is shown. The LCD panel 300 comprises a plurality of data lines, a plurality of scan lines, a plurality of voltage controlling lines, a plurality of TFTs, and a plurality of pixel units. Each of the TFTs is electrically connected to a scan line and a data line. Each of the pixel units comprises a first sub-pixel electrode 331 and a second sub-pixel electrode 332. To have a better understanding of the diagrams of the embodiment, a data line 302, a scan line 301, a voltage controlling line 307, and a TFT 303 are simply shown in the embodiment. A gate 371 of the TFT 303 is coupled to the scan line 301. A source 373 of the TFT 303 is coupled to the data line 302. A drain 374 of the TFT 303 is coupled to the first sub-pixel electrode 331 and the second sub-pixel electrode 332. The voltage controlling line 307 is used for providing a control signal.

A method of driving the LCD panel 300 is as follows: A scan signal output by a gate driver (not shown) is transmitted to a plurality of TFTs 303 through the scan line 301, and the plurality of TFTs 303 on the scan line 301 are turned on in order. Meanwhile, a corresponding data signal output by a source driver (not shown) is transmitted to the TFTs 303 through the data line 302. Then, the data signal passes through the plurality of TFTs 303 through the data line 302 and is transmitted to the first and second sub-pixel electrodes 331 and 332 so that each of the components obtains its required voltage at full charge. LCs on the first and second sub-pixel electrodes 331 and 332 twist based on a difference in voltage of the data signal, and then the first and second sub-pixel electrodes 331 and 332 show various grayscales. The gate driver outputs the scan signal row by row through the plurality of scan lines to turn on the plurality of TFTs 303 in each row. Then, the source driver charges/discharges the first and second sub-pixel electrodes 331 and 332 in each row. According to this sequence, an image will be completely shown on the LCD panel 300.

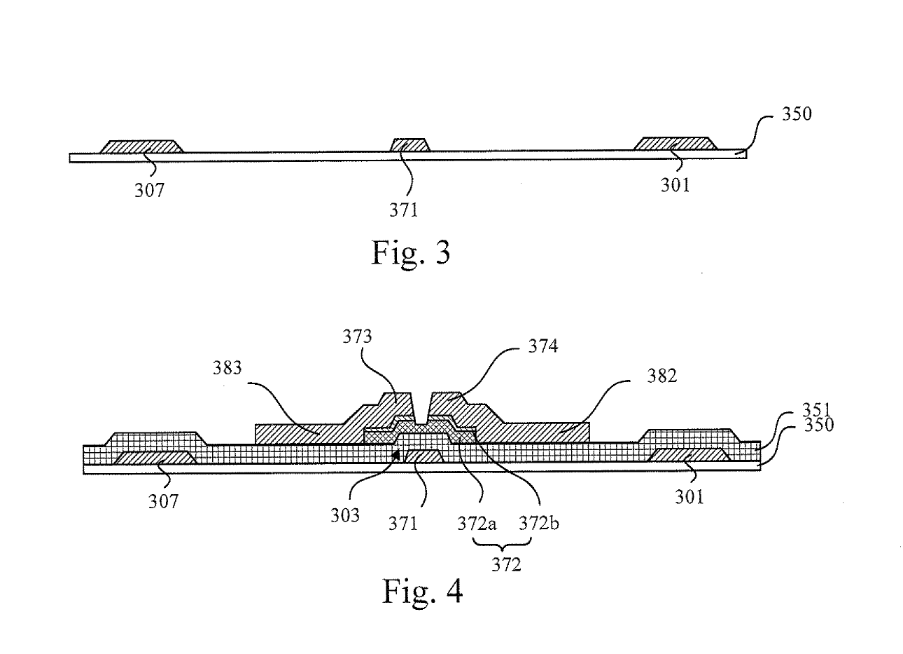

The LCD panel 300 panel manufacturing process is disclosed as follows. Referring to FIGS. 3 to 6, FIGS. 3 to 6 show a schematic diagram of forming the LCD panel 300.

Referring to FIG. 3, at first, a glass substrate 350 serves as a lower substrate. Next, a metal thin-film deposition is conducted on the glass substrate 350 to form a first metal layer (not shown) on the surface of the glass substrate 350. Also, a first photo etching process (PEP) is conducted using a first mask to etch the gate 371 of the TFT 303, the voltage controlling line 307, and the scan line 311. It will be appreciated by those skilled in the art that the gate 371 is practically part of the scan line 301.

Referring to FIG. 2 and FIG. 4, an insulating layer 351 made of silicon nitride (SiNx) is deposited and covers the gate 371, the voltage controlling line 307, and the scan line 301. An amorphous Si (a-Si) layer and an N+ a-Si layer at high electron doping concentrations are successively deposited on the insulating layer 351. Next, a second metallic layer (not shown) covers the a-Si layers and the N+ a-Si layer at high electron doping concentrations. A semiconductor layer 372 is formed after the a-Si layers and the N+ a-Si layer are etched using a second mask. Meanwhile, the second metallic layer is etched to form the source 373, the drain 374, a first conducting trace 381 (shown in FIG. 2), a second conducting trace 382, a third conducting trace 383, and the data line 302 (shown in FIG. 2) of the TFT 303. The semiconductor layer 372 comprises an a-Si layer 372a and an ohmic contact layer 372b. The a-Si layer 372a serves as a passage of the TFT 303. The ohmic contact layer 372b is used for reducing resistance. The data line 302 is connected to the source 373 through the first conducting trace 381 and to the drain 374 through the second and third conducting traces 382 and 383. Although the data line 302 is not shown in FIG. 4, it will be appreciated by those skilled in the art that the source 373 is practically part of the data line 302.

In addition, the a-Si layers, the N+ a-Si layer, and the second metallic layer are etched at the same time in the present embodiment. The structure is shown in FIG. 4. However, different steps are adopted in another embodiment. Firstly, the a-Si layers and the N+ a-Si layer are formed on the insulating layer 351. Next, the a-Si layers and the N+ a-Si layer are etched using the second mask to form the semiconductor layer 372. Next, the second metallic layer is formed on the semiconductor layer 372 and the insulating layer 351. Finally, the second metallic layer is etched using another mask to form the source 373, the drain 374, and the data line 302.

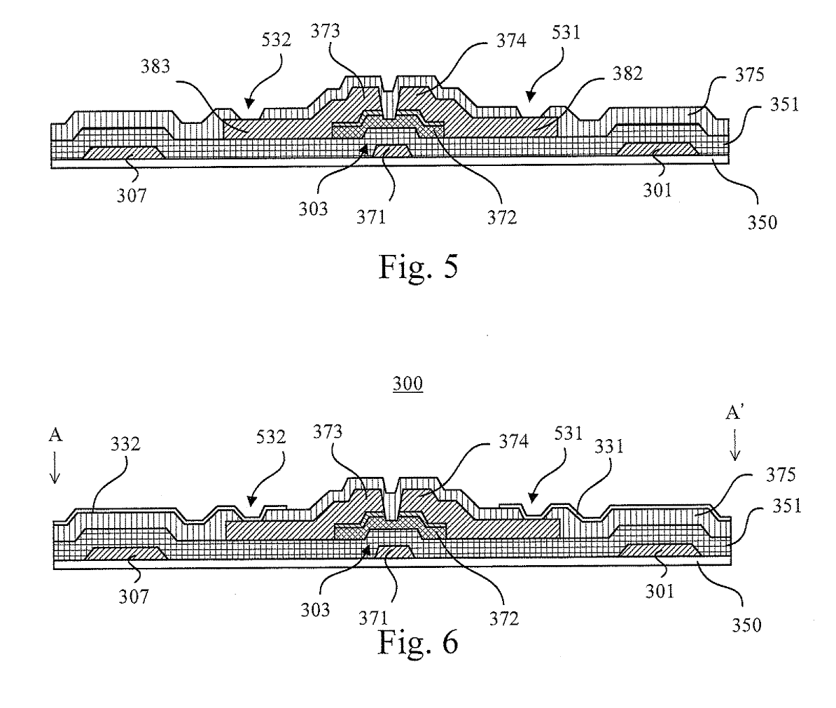

Referring to FIG. 5, a passivation layer 375 made of SiNx is deposited and covers the source 373, the drain 374, and the data line 302. Next, a third PEP is conducted using a third mask to remove part of the passivation layer 375 on the drain 374 until the surface of the drain 374 is exposed. A first via 531 and a second via 532 are formed on the drain 374. A projection of the first via 531 and the second via 532 onto the glass substrate 350 is between a projection of the scan line 301 and a projection of the voltage controlling line 307 onto the glass substrate 350 (shown in FIG. 2).

Referring to FIG. 6, FIG. 6 is a cross section view of the LCD panel 300 taken along line A-A′ of FIG. 2. A transparent conducting layer made of indium tin oxide (ITO) is formed on the passivation layer 375. Next, the first sub-pixel electrode 331 and the second sub-pixel electrode 332 are formed after the transparent conducting layer is etched using a fourth mask. The first sub-pixel electrode 331 is electrically connected to the drain 374 of the TFT 303 through the first via 531 and the second conducting trace 382 which are formed in advance. The second sub-pixel electrode 332 is electrically connected to the drain 374 through the second via 532 and the third conducting trace 383 which are formed in advance.

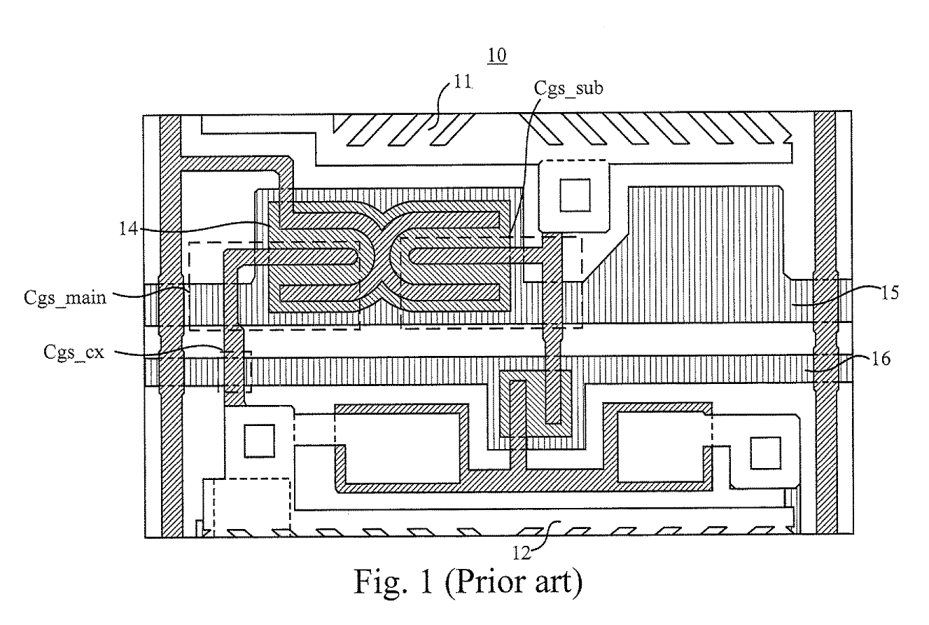

Referring to FIG. 2, the projection of the first via 531 and the second via 532 onto the glass substrate 350 is between the projection of the scan line 301 and the projection of the voltage controlling line 307 onto the glass substrate 350. Parasitic capacitances C_{gs}_{_{—}}^{main}, C_{gs}_{_{—}}^{sub}, and C_{gs}_{_{—}}^{cx} among the second and third conducting traces 382 and 383 and the scan line 301/the voltage controlling line 307 are lower. The second and third conducting traces 382 and 383 are formed by the transparent conducting layer made of indium tin oxide (ITO). Moreover, the second and third conducting traces 382 and 383 are separated from the scan line 301/the voltage controlling line 307 (i.e., the first metallic layer) by the insulating layer 351 and the passivation layer 375. According to a test result, the parasitic capacitance C_{gs}_{_{—}}^{sub} drops to about 3.9 percent, the parasitic capacitance C_{gs}_{_{—}}^{main} drops to about 32.7 percent, and the parasitic capacitance C_{gs}_{_{—}}^{cx} drops to about 3.9 percent. Because a capacitance is inversely proportional to the distance of any two conductors between them, the parasitic capacitances formed by the second and third conducting traces 382 and 383 and the scan line 301/the voltage controlling line 307 are lower than the parasitic capacitances existing in the conventional technology shown in FIG. 1.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A liquid crystal display (LCD) panel, comprising:
a glass substrate;
a thin-film transistor (TFT), comprising a gate, a source, and a drain;
a first sub-pixel electrode and a second sub-pixel electrode, electrically connected to the TFT and formed by a transparent conducting layer;
a scan line, formed by a first metallic layer, disposed on the glass substrate, and coupled to the gate of the TFT, for transmitting a scan signal;
a voltage controlling line, formed by the first metallic layer and disposed on the glass substrate, for transmitting a control signal;
an insulating layer, disposed on the scan line and on the voltage controlling line;
a data line, formed by a second metallic layer, disposed on the insulating layer, and coupled to the source of the TFT;
a passivation layer, disposed in the second metallic layer; and
a first via and a second via, formed in the passivation layer and disposed between the scan line and the voltage controlling line, wherein the first sub-pixel electrode is electrically connected to the drain of the TFT through the first via, and the second sub-pixel electrode is electrically connected to the drain of the TFT through the second via.

2. The LCD panel of claim 1, wherein the TFT further comprises a first conducting trace, a second conducting trace, and a third conducting trace, the source directly connected to the data line through the first conducting trace, the drain directly connected to the first sub-pixel electrode through the second conducting trace and the first via, and the drain directly connected to the second sub-pixel electrode through the third conducting trace and the second via.

3. The LCD panel of claim 2, wherein a projection of the first via and the second via onto the glass substrate is between a projection of the scan line and a projection of the voltage controlling line onto the glass substrate.

4. The LCD panel of claim 2, wherein the transparent conducting layer is made of indium tin oxide (ITO).

5. The LCD panel of claim 1, wherein the TFT, the scan line, and the voltage controlling line disposed between the first sub-pixel electrode and the second sub-pixel electrode.

6. A method of manufacturing an LCD panel, comprising:
providing a glass substrate;
forming a first metallic layer on the glass substrate;
etching the first metallic layer to form a gate of a TFT, a voltage controlling line and a scan line;
forming an insulating layer on the gate of the TFT, the voltage controlling line, and the scan line;
forming a second metallic layer and etching the second metallic layer to form a source and a drain of the TFT and a data line;
forming a passivation layer on the second metallic layer;
etching the passivation layer to form a first via and a second via, the first and second vias disposed between the scan line and the voltage controlling line; and
forming a transparent conducting layer and etching the transparent conducting layer to form a first sub-pixel electrode and a second sub-pixel electrode, wherein the first sub-pixel electrode is electrically connected to the drain of the TFT through the first via, and the second sub-pixel electrode is electrically connected to the drain of the TFT through the second via.

7. The method of claim 6, wherein the step of etching the transparent conducting layer to form a first sub-pixel electrode and a second sub-pixel electrode further comprises etching the transparent conducting layer to form a first conducting trace, a second conducting trace, and a third conducting trace, so that the source directly connected to the data line through the first conducting trace, the drain directly connected to the first sub-pixel electrode through the second conducting trace and the first via, and the drain directly connected to the second sub-pixel electrode through the third conducting trace and the second via.

8. The method panel of claim 6, wherein a projection of the first via and the second via onto the glass substrate is between a projection of the scan line and a projection of the voltage controlling line onto the glass substrate.

9. The method of claim 6, wherein the transparent conducting layer is made of indium tin oxide (ITO).

10. The method of claim 6, wherein the TFT, the scan line, and the voltage controlling line disposed between the first sub-pixel electrode and the second sub-pixel electrode.
